(19) United States
(12) Patent Application Publication
(10) Pub. No.: US 2025/0183207 A1
(43) Pub. Date: Jun. 5, 2025

(54) SEMICONDUCTOR INTEGRATED CIRCUIT DEVICE

(71) Applicant: Socionext Inc., Kanagawa (JP)

(72) Inventors: Toru MATSUI, Yokohama-shi (JP); Masato NAKOSHI, Yokohama-shi (JP)

(21) Appl. No.: 19/037,636

(22) Filed: Jan. 27, 2025

Related U.S. Application Data
(63) Continuation of application No. PCT/JP2022/032178, filed on Aug. 26, 2022.

(51) Int. Cl. H01L 23/00; H01L 21/66

(52) U.S. Cl. CPC H01L 24/05; H01L 22/32; H01L 24/06; H01L 2224/0401; H01L 2224/05552; H01L 2224/06051; H01L 2224/06133; H01L 2224/06517

(57) ABSTRACT

In a semiconductor integrated circuit device, a first interconnect layer includes: a plurality of electrode pads arranged in a first direction and connected to a first power supply; and a first interconnect extending in the first direction and connecting the plurality of electrode pads mutually. A second interconnect layer includes a second interconnect extending in the first direction, having a first overlap portion overlapping the first interconnect in planar view, and connected to the first interconnect. Each of the plurality of electrode pads includes an probing electrode pad and an bump-forming electrode pad. The second interconnect has a second overlap portion overlapping the probing electrode pad in planar view.

### CROSS-REFERENCE TO RELATED APPLICATIONS

This is a continuation of International Application No. PCT/JP2022/032178 filed on Aug. 26, 2022. The entire disclosure of this application is incorporated by reference herein.

### BACKGROUND

The present disclosure relates to a semiconductor integrated circuit device provided with electrode pads, and more particularly to a semiconductor integrated circuit device having electrode pads and interconnects laid under the electrode pads.

With the scale of a semiconductor integrated circuit device becoming increasingly larger, the number of electrode pads for connection with external signals and external power supplies is increasing in the semiconductor integrated circuit device. To address this, presently, interconnects are generally laid under the electrode pads.

In the case of laying interconnects under electrode pads, in a region in which electrode pads are in contact with a probe in a probing process, there may arise a problem in the reliability of underlying interconnects due to stress, etc. exerted on such electrode pads. This problem is particularly prominent when no bumps for assembly are formed in the probe contact region.

In Japanese Unexamined Patent Publication No. 2009-76808, while an interconnect connected to an electrode pad is laid right under the position of the electrode pad coming into contact with a probe, an interconnect that is not connected to an electrode pad is laid under the position of the electrode pad that does not contact the probe. With this, while the problem of the reliability due to contact of a probe is solved, the number of electrodes capable of being placed is kept from decreasing (see FIG. 6 of the cited patent document).

However, in the conventional technique like the one in the cited patent document, in order to avoid laying of interconnects that are not connected to electrode pads right under the probe contact positions, it is necessary to cut partly or divert the interconnects right under the probe contact positions. This raises a problem of increasing the resistance value of the interconnects.

In particular, when the interconnects are power lines, in which there are increasing requests for reducing the resistance of power lines because the voltage is becoming lower and power consumption is increasing in the semiconductor integrated circuit device, problems of decrease in operating speed and malfunction due to occurrence of a power supply voltage drop arise.

Moreover, when flip mounting is executed to a package substrate or an interposer with bumps provided on electrode pads, the electrode pads are to be placed over the entire faces of a chip, not only on the periphery of the chip. Therefore, the above problems are more prominent.

An objective of the present disclosure is to solve the above-described problems.

### SUMMARY

According to the first mode of the disclosure, a semiconductor integrated circuit device includes: a plurality of electrode pads arranged in a first direction in a first interconnect layer and connected to a common power supply; a first interconnect extending in the first direction in the first interconnect layer and connecting the plurality of electrode pads mutually; and a second interconnect extending in the first direction in a second interconnect layer located one layer below the first interconnect layer, having a first overlap portion overlapping the first interconnect in planar view, and connected to the first interconnect, wherein each of the plurality of electrode pads includes a probing electrode pad and a bump-forming electrode pad, and the second interconnect has a second overlap portion overlapping the probing electrode pad of each of the electrode pads in planar view.

As described above, by arranging a plurality of electrode pads connected to a common power supply in the first direction, the first interconnect in the first interconnect layer (e.g., MT layer) can be continuously formed in the first direction without discontinuity. With this, the interconnect resistance of the first interconnect can be reduced.

Moreover, the second interconnect in the second interconnect layer (e.g., Mx layer) is formed to have a first overlap portion overlapping the first interconnect and a second overlap portion overlapping the probing electrode pad. In this way, by laying the second interconnect in addition to the first interconnect, the interconnect resistance can be further reduced, and therefore occurrence of a power supply voltage drop can be prevented or reduced.

Since the first interconnect and the second interconnect are connected to a common power supply, even though the probing electrode pad and the second interconnect have a second overlap portion, the problem of decrease in reliability due to contact of a probe with a probing electrode pad does not occur.

According to the semiconductor integrated circuit device of the present disclosure, it is possible to prevent or reduce occurrence of a power supply voltage drop while avoiding decrease in reliability due to contact of a probe with a probing electrode pad.

### BRIEF DESCRIPTION OF THE DRAWINGS

FIG. 1 shows a layout example of a first interconnect layer of a semiconductor integrated circuit device according to the first embodiment.

FIG. 2 shows a layout example of a second interconnect layer in range II in FIG. 1.

FIG. 3 is an enlarged view of range III in FIG. 2.

FIG. 4 is an enlarged view of range IV in FIG. 2.

FIG. 5 is an enlarged view of range V in FIG. 2.

FIG. 6 is a view equivalent of FIG. 2, showing another configuration example of the first embodiment.

FIG. 7 is a view showing another configuration example of electrode pads.

FIG. 8 is an enlarged view of range VIII in FIG. 7.

FIG. 9 is a plan view schematically showing the entire configuration of a semiconductor integrated circuit device according to the second embodiment.

FIG. 10 shows a layout example of a first interconnect layer in range X in FIG. 9.

### DETAILED DESCRIPTION

Embodiments of the present disclosure will be described hereinafter with reference to the accompanying drawings. Note that, as used herein, ‘VDD’ and ‘VSS’ denote power supply voltages or power supplies themselves.

### First Embodiment

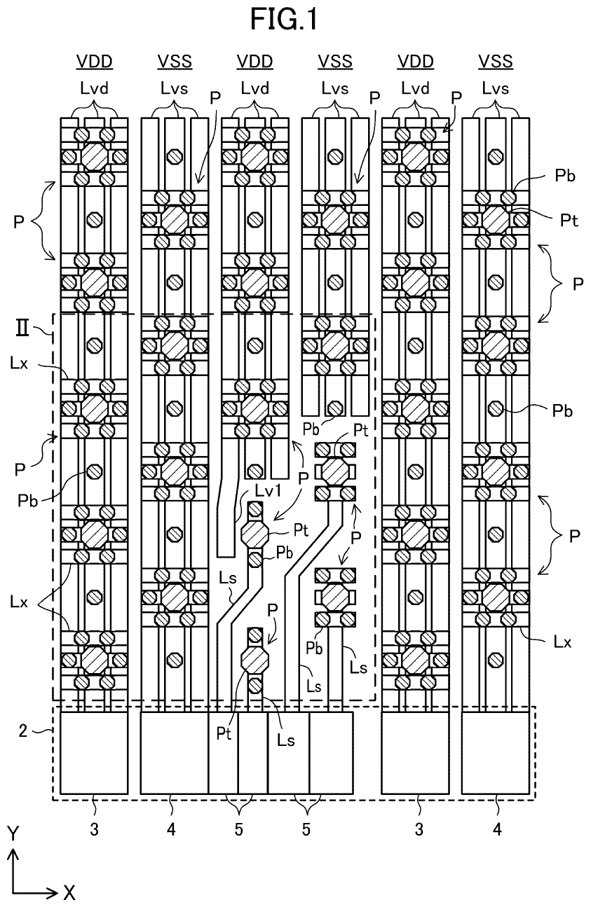

FIGS. 1 to 5 show a layout example of a semiconductor integrated circuit device of this embodiment. In the plan views of FIGS. 1 to 5, it is herein decided that the horizontal direction in the figure is the X direction (corresponding to the second direction) and the vertical direction in the figure is the Y direction (corresponding to the first direction).

FIG. 1 shows an example of the layout of a first interconnect layer (e.g., MT layer) of the semiconductor integrated circuit device, illustrating only electrode pads P and interconnects. Although the electrode pads P are hatched for convenience of description, the electrode pads P and the interconnects are formed in the same first interconnect layer.

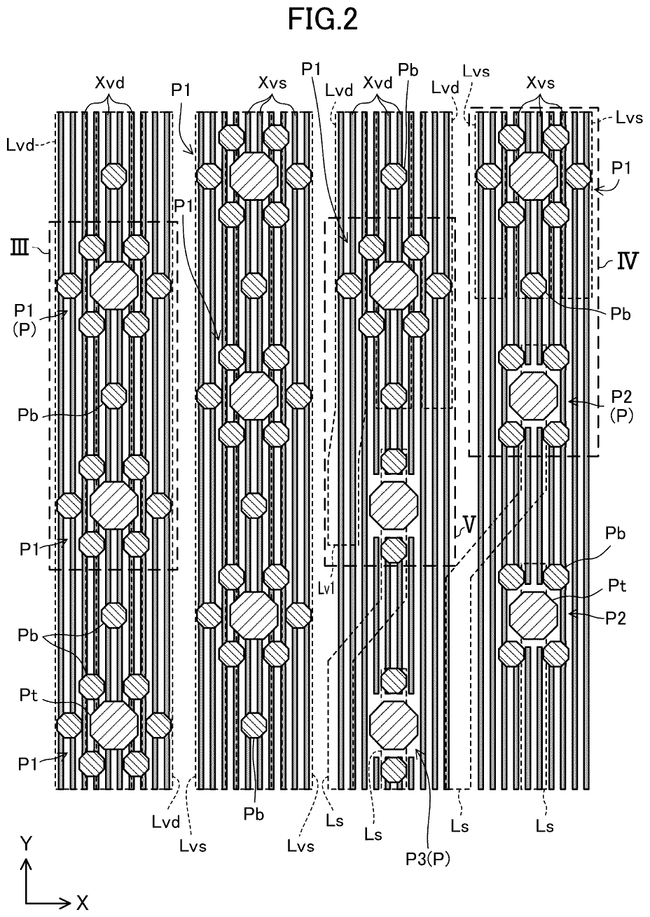

FIG. 2 shows an example of the interconnect layout of a second interconnect layer (e.g., Mx layer) located one layer below the first interconnect layer in range II in FIG. 1. Note that, in FIG. 2, the interconnects in the first interconnect layer are indicated by the broken lines and the electrodes pads in the first interconnect layer are hatched and indicated by the solid lines as in FIG. 1.

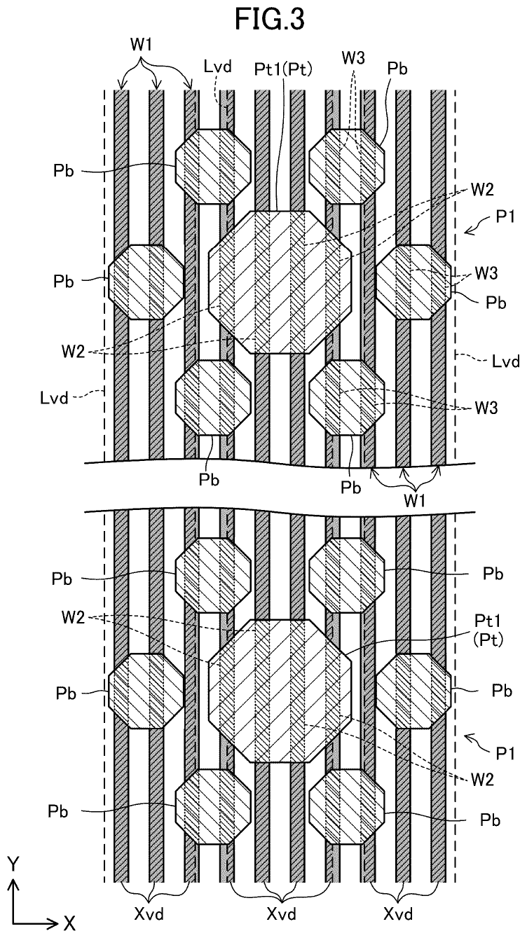

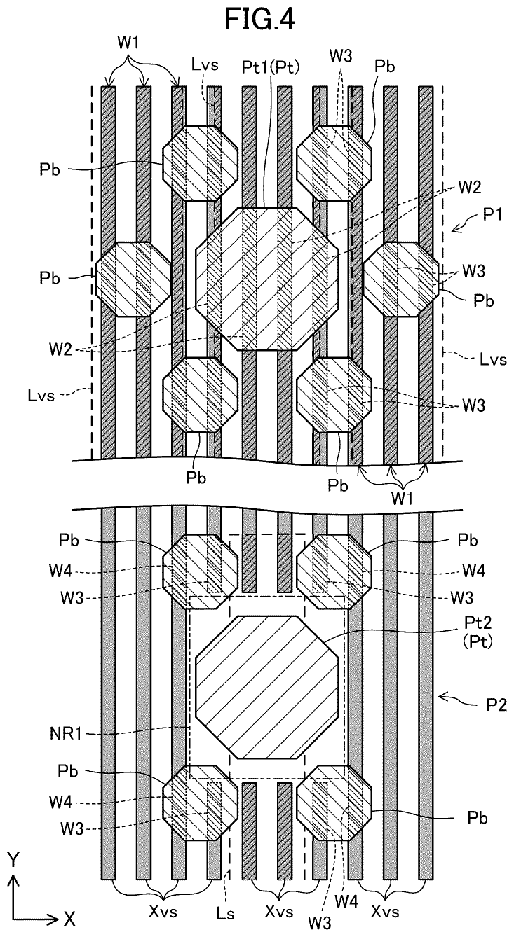

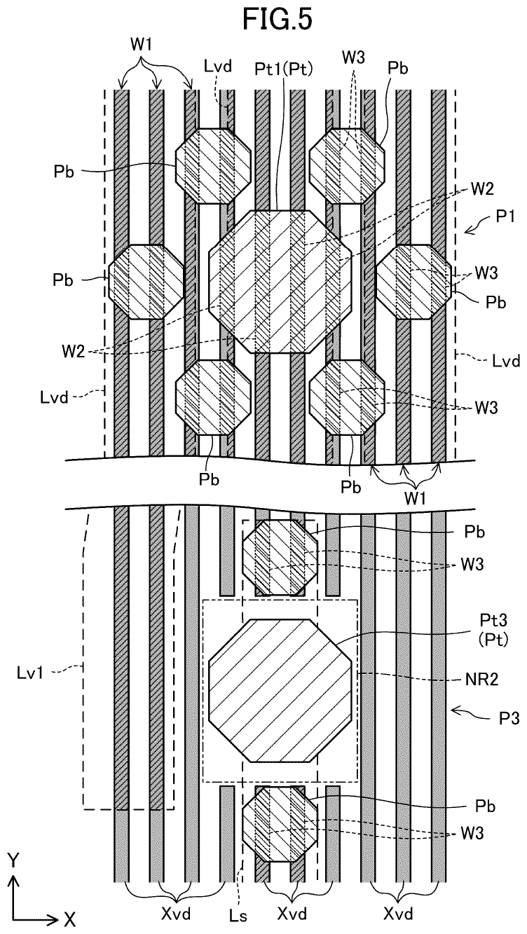

FIG. 3 is an enlarged view of range III in FIG. 2, FIG. 4 is an enlarge view of range IV in FIG. 2, and FIG. 5 is an enlarged view of range V in FIG. 2. In FIGS. 3 to 5, illustration of interconnects Lx is omitted.

As shown in FIG. 1, electrode pads P each include a probing electrode pad Pt with which a probe is in contact during probing and a bump-forming electrode pad Pb for forming a bump for connection with a package substrate or an interposer. For convenience of description, the probing electrode pads Pt are hatched with right upward lines and the bump-forming electrode pads Pb are hatched with right downward lines.

The probing electrode pads Pt are arranged in the X direction and the Y direction at predetermined pitches. Also, adjacent probing electrode pads Pt in the X direction are arranged in a staggered fashion, where the positions in the Y direction are alternately displaced. With this configuration, the placement density of the electrode pads P can be increased while the distance between the electrode pads P is secured so that no problem will occur at the time of bump formation and other types of assembly.

Around each of the probing electrode pads Pt provided are bump-forming electrode pads Pb of the number corresponding to the current to flow. In the example of FIG. 1, the probing electrode pads Pt and the bump-forming electrode pads Pb are formed separately from each other, and six, four, or two bump-forming electrode pads Pb are provided around each probing electrode pad Pt. In this example, the probing electrode pads Pt and the bump-forming electrode pads Pb have an octagonal shape, and the bump-forming electrode pads Pb are smaller in size than the probing electrode pads Pt. However, the shape of the electrode pads P is not limited to an octagon, but may be any other polygon or a circle. Also, each probing electrode pad Pt and the surrounding bump-forming electrode pads Pb may be formed integrally. A configuration example of integral formation of the probing electrode pad Pt and the surrounding bump-forming electrode pads Pb will be described later.

In the following description, the probing electrode pads Pt may be grouped into a “first probing electrode pad Pt1” around which six bump-forming electrode pads Pb are provided, a “second probing electrode pad Pt2” around which four bump-forming electrode pads Pb are provided, and a “third probing electrode pad Pt3” around which two bump-forming electrode pads Pb are provided, and described separately. Also, the electrode pads P may be grouped into a “first electrode pad P1” that includes the first probing electrode pad Pt1, a “second electrode pad P2” that includes the second probing electrode pad Pt2, and a “third electrode pad P3” that includes the third probing electrode pad Pt3, and described separately.

In the first electrode pad P1, six bump-forming electrode pads Pb are placed to surround the first probing electrode pad Pt1 at an equal pitch in the circumferential direction. The six bump-forming electrode pads Pb are placed to be equal in the distance from the center of the probing electrode pad Pt and also equal in the angle formed by two virtual lines connecting the center of the probing electrode pad Pt with the centers of every two adjacent bump-forming electrode pads Pb. Moreover, the six bump-forming electrode pads Pb are placed to secure the minimum pitch in design rules from the first probing electrode pad Pt1. In addition, the bump-forming electrode pads Pb that are the same in position in the Y direction, among the six bump-forming electrode pads Pb, are mutually connected through an interconnect Lx extending in the X direction. In the present disclosure, the first electrode pads P1 are used as electrode pads for VDD or electrode pads for VSS.

In the second electrode pad P2, four bump-forming electrode pads Pb are placed to surround the second probing electrode pad Pt2 as described above. In the present disclosure, the second electrode pads P2 are used as electrode pads for signals.

In the third electrode pad P3, each one bump-forming electrode pad Pb is placed on both sides of the third probing electrode pad Pt3 in the Y direction with the center positions of these pads in the X direction being aligned. In the present disclosure, the third electrode pads P3 are used as electrode pads for signals.

Since a large amount of current flows to the first probing electrode pads Pt1, additional bump-forming electrode pads Pb are provided at positions a little distant from the first probing electrode pads Pt1 in the Y direction. In the example of FIG. 1, each one additional bump-forming electrode pad Pb is provided at the center position between the adjacent probing electrode pads Pt in the Y direction.

### Electrode Pad Arrangement Example (1)

First, an example in which a plurality of first electrode pads P1 are arranged in the Y direction will be described. Two columns each on the right and left in FIG. 1, and two columns on the left in FIG. 2, correspond to this arrangement example.

As shown in the leftmost column in FIG. 2, the first electrode pads P1 for VDD arranged in the Y direction are mutually connected through power lines Lvd (corresponding to the first interconnects) extending in the Y direction. The power lines Lvd are connected to an IO cell 3 for VDD placed in an IO block 2 (see FIG. 1).

As shown in the second column from the left in FIG. 2, the first electrode pads P1 for VSS arranged in the Y direction are mutually connected through power lines Lvs (corresponding to the first interconnects) extending in the Y direction. The power lines Lvs are connected to an IO cell 4 for VSS placed in the IO block 2.

In the following description, the power lines Lvd and the power lines Lvs may be collectively called the “power lines Lv” when they are described without distinction from each other.

Each three power lines Lv extending in parallel in the Y direction constitute one set. Note however that the number of power lines Lv constituting one set is not limited to three.

As shown in FIG. 2, in the second interconnect layer, power lines Xvd (corresponding to the second interconnects) and power lines Xvs (corresponding to the second interconnects) extending in the Y direction are laid. The power supply voltage VDD is supplied to the power lines Xvd, and the power supply voltage VSS is supplied to the power lines Xvs.

In the following description, the power lines Xvd and the power lines Xvs formed in the second interconnect layer may be collectively called “power lines Xv” when they are described without distinction from each other.

The power lines Xv are laid to underlie the power lines Lv. In other words, the power lines Xv have first overlap portions W1 overlapping the power lines Lv in planar view. FIG. 3 illustrates the first overlap portions W1 between the power lines Xvd and the power lines Lvd.

The power lines Lv and the power lines Xv are mutually connected through contacts (not shown). In this example, ten power lines Xv extending in parallel in the Y direction constitute one set. These ten power lines are mutually connected through interconnects (not shown) in a lower layer below the second interconnect layer. The power supply voltages are supplied to transistors (not shown) placed below through the interconnects in the lower layer. Note that the shape of the power lines Xv is not limited to the configuration of one set of ten lines extending in parallel in the Y direction.

As shown in FIG. 3, the power lines Xvd have second overlap portions W2 overlapping the first probing electrode pad Pt1 constituting the first electrode pad P1 in planar view. In this example, four lines in the center, among the ten power lines Xvd, have second overlap portions W2 overlapping the first probing electrode pads Pt1 arranged in the Y direction in planar view.

Moreover, the power lines Xvd have third overlap portions W3 overlapping the six bump-forming electrode pads Pb surrounding the first probing electrode pad Pt1 in planar view. In this example, each two lines on both sides in the X direction, among the ten power lines Xvd, have third overlap portions W3 overlapping the bump-forming electrode pads Pb placed on both sides of each first probing electrode pad Pt1 in the X direction in planar view. Also, the third and fourth lines from both sides in the X direction, among the ten power lines Xvd, have third overlap portions W3 overlapping the bump-forming electrode pads Pb placed at positions oblique from each first probing electrode pad Pt1 in planar view.

In summary, by arranging the first electrode pads P1 connected to the same power supply in a line in the Y direction, the power lines Lv in the first interconnect layer (e.g., MT layer) can be formed continuously in the Y direction without discontinuity. With this, the interconnect resistance of the power lines Lv can be reduced.

Moreover, the power lines Xv in the second interconnect layer (e.g., Mx layer) are formed to extend in the Y direction overlapping the power lines Lv, and the upper and lower power lines Lv and Xv are mutually connected. With this, the interconnect resistance can be further reduced compared with the case of forming power lines only in the first interconnect layer, and therefore occurrence of a power supply voltage drop can be prevented or reduced.

As described above, the power lines Lvd and the power lines Wvd placed to overlap each other are both connected to VDD, having the same power supply voltage VDD. Therefore, even though the first probing electrode pad Pt1 and the power lines Xvd have second overlap portions W2, problems such as decrease in reliability due to contact of a probe with the first probing electrode pad Pt1 will not occur. This also applies to the relationship between the power lines Lvs and the power lines Wvs.

### Electrode Pad Arrangement Example (2)

Next, an example in which a plurality of first electrode pads P1 are arranged in the Y direction and also the second electrode pads P2 are arranged in the same column will be described. In FIGS. 1 and 2, the fourth column from the left corresponds to this arrangement example. Note that, since the arrangement of a plurality of first electrode pads P1 in the Y direction is the same as that described above in “Electrode Pad Arrangement Example (1),” description here will be made centering on the relationship between the first electrode pad P1 and the second electrode pad P2.

FIG. 4 is an enlarged view of range IV in FIG. 2, in which the first electrode pad P1 (upper part of FIG. 4) and the second electrode pad P2 (lower part of FIG. 4) are arranged in the Y direction.

In FIG. 4, the first electrode pad P1 is formed in the first interconnect layer and connected to the power lines Lvs extending in the Y direction in the first interconnect layer. In the second interconnect layer, formed are the power lines Xvs (corresponding to the third interconnects) that extend in the Y direction and are laid to underlie the power lines Lvs. That is, the power lines Xvs and the power lines Lvs have first overlap portions W1 as in FIG. 3 described above.

Also, as in FIG. 3 described above, the power lines Xvs have second overlap portions W2 overlapping the first probing electrode pad Pt1 constituting the first electrode pad P1 in planar view, and also have third overlap portions W3 overlapping the six bump-forming electrode pads Pb surrounding the first probing electrode pad Pt1 in planar view.

As shown in FIG. 4, the second electrode pad P2 includes four bump-forming electrode pads Pb placed around the second probing electrode pad Pt2. The positions of the four bump-forming electrode pads Pb correspond to the positions of four bump-forming electrode pads Pb, out of the six bump-forming electrode pads Pb of the first electrode pad P1, excluding the two bump-forming electrode pads Pb placed on both sides of the first probing electrode pad Pt1 in the X direction. Also, the first electrode pad P1 and the second electrode pad P2 are placed so that the positions of the first probing electrode pad Pt1 and the second probing electrode pad Pt2 in the X direction are the same.

A signal line Ls is connected to the second electrode pad P2. The signal line Ls is an example of the second interconnects formed separately from the power lines Lv (Lvd and Lvs) corresponding to the first interconnects. The signal line Ls is connected to an IO cell 5 for signals.

The power lines Lvs do not extend up to the second probing electrode pad Pt2 but discontinue somewhere between the first electrode pad P1 and the second electrode pad P2.

The power lines Xvs are laid to avoid overlaps with the second probing electrode pad Pt2 of the second electrode pad P2 in planar view. Specifically, in the second interconnect layer, an non-interconnect region NR1 of a predetermined breadth covering the region under the second probing electrode pad Pt2 is provided, and no power lines Xvs are laid in the non-interconnect region NR1. In the example of FIG. 4, four lines in the center, among the ten power lines Xvs, are not laid in the non-interconnect region NR1, but discontinued. This prevents occurrence of the problems such as decrease in reliability due to contact of a probe (not shown) with the probing electrode pad Pt. Note that the set range of the non-interconnect region NR1 is not specifically limited, but is based on the range of contact of the probe with the probing electrode pad Pt, for example.

On the other hand, for the bump-forming electrode pads Pb, the above problem of decrease in reliability does not occur. Therefore, the power lines Xvs can be formed outside the set range of the non-interconnect region NR1, including the positions of the bump-forming electrode pads Pb. In the example of FIG. 4, six lines other than the four lines in the center, among the ten power lines Xvs, are formed continuously in the Y direction including the region of the second electrode pad P2 without discontinuity.

As shown in FIG. 4, the four bump-forming electrode pads Pb of the second electrode pad P2 are formed in the region outside the non-interconnect region NR1 in planar view. In this region, the power lines Xvs extend to overlap the bump-forming electrode pads Pb in planar view. In other words, the power lines Xvs have third overlap portions W3 overlapping the bump-forming electrode pads Pb of the second electrode pad P2 in planar view.

Also, the bump-forming electrode pads Pb of the second electrode pad P2 are formed to have outer portions protruding outside from the second probing electrode pad Pt2 and the non-interconnect region NR1 in the X direction in planar view. In such outer portions, the power lines Xvs can be laid so that both the bump-forming electrode pads Pb arranged in the Y direction have overlap portions W4 (corresponding to fourth overlap portions) with one continuous line.

Although not illustrated, the above also applies to the case of arranging the second electrode pad P2 with the first electrode pad P1 for VDD in the Y direction.

As described above, in this arrangement example, as in “Electrode Pad Arrangement Example (1)”, the power lines Lvs in the first interconnect layer and the power lines Xvs in the second interconnect layer are formed to have the first overlap portions W1 and the second overlap portions W2. With this, as in “Electrode Pad Arrangement Example (1),” the interconnect resistance can be further reduced compared with the case of one-layer interconnects, and therefore the effect of preventing or reducing occurrence of a power supply voltage drop can be obtained.

Moreover, the power lines Xvs in the second interconnect layer are laid not to underly the second probing electrode pad Pt2 of the second electrode pad P2, which is arranged in line with the first electrode pad P1 in the Y direction, but to underly the bump-forming electrode pads Pb. With this, occurrence of a power supply voltage drop can be prevented or reduced without causing the problem of reliability.

### Electrode Pad Arrangement Example (3)

Next, an example in which a plurality of first electrode pads P1 are arranged in the Y direction and also the third electrode pads P3 are arranged in the same column will be described. In FIGS. 1 and 2, the third column from the left corresponds to this arrangement example. Note that, since the arrangement of a plurality of first electrode pads P1 in the Y direction is the same as that described above in “Electrode Pad Arrangement Example (1),” description here will be made centering on the relationship between the first electrode pad P1 and the third electrode pad P3.

FIG. 5 is an enlarged view of range V in FIG. 2, in which the first electrode pad P1 (upper part of FIG. 5) and the third electrode pad P3 (lower part of FIG. 5) are arranged in the Y direction.

In FIG. 5, the first electrode pad P1 is formed in the first interconnect layer and connected to the power lines Lvd extending in the Y direction in the first interconnect layer. In the second interconnect layer, formed are the power lines Xvd (corresponding to the third interconnects) that extend in the Y direction and are laid to underlie the power lines Lvd. That is, the power lines Xvd and the power lines Lvd have first overlap portions W1 as in FIG. 3 described above.

Also, as in FIG. 3, the power lines Xvd have second overlap portions W2 overlapping the first probing electrode pad Pt1 constituting the first electrode pad P1 in planar view, and also have third overlap portions W3 overlapping the six bump-forming electrode pads Pb surrounding the first probing electrode pad Pt1 in planar view.

The power lines Xvd are laid to avoid overlaps with the third probing electrode pad Pt3 of the third electrode pad P3 in planar view. Specifically, in the second interconnect layer, a non-interconnect region NR2 of a predetermined breadth covering the region under the third probing electrode pad Pt3 is provided, and no power lines Xvd are laid in the non-interconnect region NR2. In the example of FIG. 5, four lines in the center, among the ten power lines Xvd, are not laid in the non-interconnect region NR2, but discontinued. This prevents occurrence of problems such as decrease in reliability due to contact of a probe (not shown) with the probing electrode pad Pt.

On the other hand, for the bump-forming electrode pads Pb, the above problem of decrease in reliability does not occur. Therefore, the power lines Xvd can be formed outside the set range of the non-interconnect region NR2, including the positions of the bump-forming electrode pads Pb.

In FIG. 5, the third electrode pad P3 includes two bump-forming electrode pads Pb placed on the upper and lower sides of the third probing electrode pad Pt3 in the figure at positions aligned in the X direction. When the number of bump-forming electrode pads Pb is small as in this case (two in the example of FIG. 5), the bump-forming electrode pads Pb and the third probing electrode pad Pt3 may be arranged in line in the Y direction. With this arrangement, it becomes easy to lay other signal lines Ls and power lines Lv in the first interconnect layer on the sides of the third probing electrode pad Pt3 in the X direction. In this example, a power line Lv1 connected to the power line Lvd is formed on the left side of the third probing electrode pad Pt3 in the X direction in the figure.

Since the two bump-forming electrode pads Pb are formed outside the set range of the non-interconnect region NR2, the power lines Xvd are formed to have third overlap portions W3 overlapping the bump-forming electrode pads Pb.

As described above, in this arrangement example, also, the same effects obtained in “Electrode Pad Arrangement Example (2)” described above are obtained. Specifically, the power lines Lvd in the first interconnect layer and the power lines Xvd in the second interconnect layer are formed to have the first overlap portions W1 and the second overlap portions W2. With this, the interconnect resistance can be further reduced compared with the case of one-layer interconnects, and therefore occurrence of a power supply voltage drop can be prevented or reduced.

Moreover, the power lines Xvd in the second interconnect layer are laid not to underly the third probing electrode pad Pt3 of the third electrode pad P3, which is arranged in line with the first electrode pad P1 in the Y direction, but to underly the bump-forming electrode pads Pb. With this, occurrence of a power supply voltage drop can be prevented or reduced without causing the problem of reliability.

### Other Configuration Examples of First Embodiment

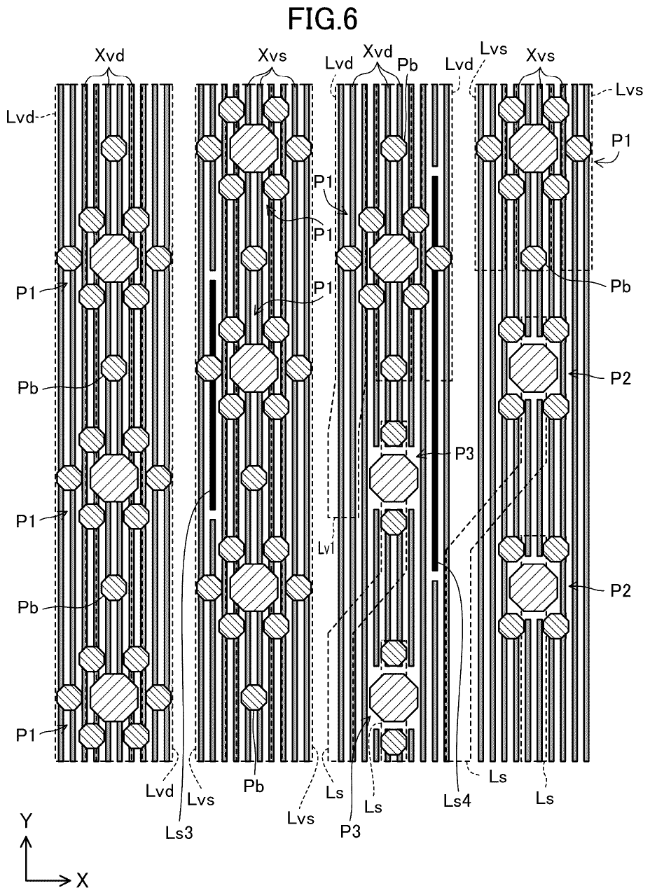

FIG. 6 is a view equivalent of FIG. 2, showing another configuration example of the first embodiment. In the example of FIG. 6, signal lines Ls3 and Ls4 that extend in the Y direction and are formed separately from the power lines Xv are provided in place of part of the power lines Xv in the second interconnect layer in FIG. 2.

The signal lines Ls3 and Ls4 are laid not to underlie the first probing electrode pad Pt1 of the first electrode pad P1, and to avoid the non-interconnect regions NR1 and NR2 described above. On the other hand, the signal lines Ls3 and Ls4 are laid to underlie the bump-forming electrode pads Pb, i.e., to have overlap portions overlapping the bump-forming electrode pads Pb in planar view.

In the example of FIG. 6, the signal line Ls3 is formed to overlap the bump-forming electrode pad Pb of the first electrode pad P1 for VSS in planar view. Also, the signal line Ls4 is formed to overlap the bump-forming electrode pad Pb of the first electrode pad P1 for VDD in planar view.

The second interconnect layer (e.g., Mx layer) is larger in thickness and smaller in resistance value than its underlying interconnect layer (e.g., an interconnect layer closest to transistors). Therefore, by using interconnects in the second interconnect layer for signal lines (e.g., clock lines) that tend to be long and large in resistance value, the resistance value can be reduced. By doing this, the delay value and delay variations of the signal lines (signal lines Ls3 and Ls4 in this example) can be reduced.

Also, in the example of FIG. 6, power lines Xv extending in the Y direction are laid on both sides of each of the signal lines Ls3 and Ls4 extending in the Y direction. With this arrangement, when the signal lines Ls3 and Ls4 are clock lines, for example, since there are no nearby signal lines, the problem of crosstalk does not occur, and variations in the delay value of the clock signals passing through the signal lines Ls3 and Ls4 can be prevented or reduced.

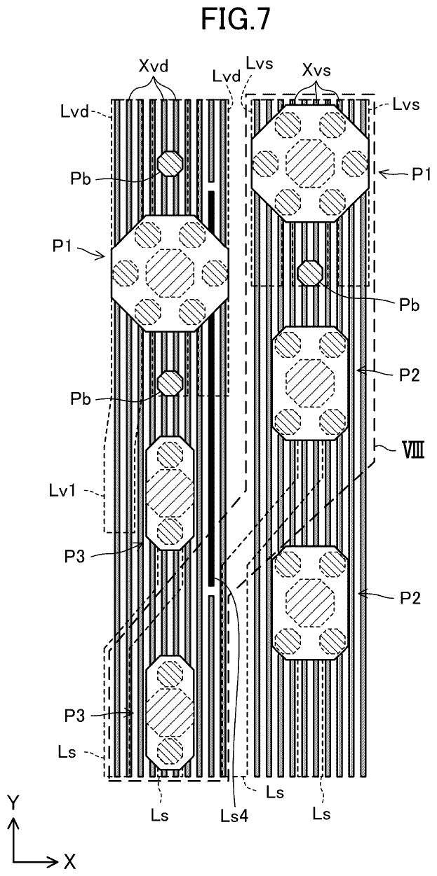

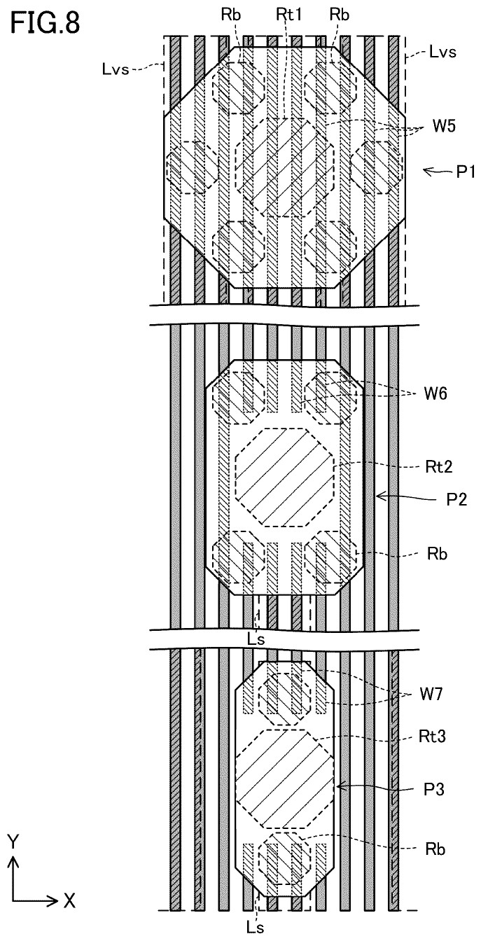

FIG. 7 is a view showing another configuration example of electrode pads, corresponding to the right half of FIG. 6. FIG. 8 is an enlarged view of range VIII in FIG. 7.

As shown in FIGS. 7 and 8, in each of the first electrode pad P1, the second electrode pad P2, and the third electrode pad P3, the probing electrode pad Pt and the bump-forming electrode pads Pb may be formed integrally.

As shown in FIG. 8, in an integral first electrode pad P1, a probing electrode region Rt1 corresponding to the first probing electrode pad Pt1 is provided. Also, bump-forming electrode regions Rb corresponding to the bump-forming electrode pads Pb are provided to surround the probing electrode region Rt1.

In an integral second electrode pad P2, a probing electrode region Rt2 corresponding to the second probing electrode pad Pt2 is provided. Also, bump-forming electrode regions Rb corresponding to the bump-forming electrode pads Pb are provided to surround the probing electrode region Rt2.

In an integral third electrode pad P3, a probing electrode region Rt3 corresponding to the third probing electrode pad Pt3 is provided. Also, bump-forming electrode regions Rb corresponding to the bump-forming electrode pads Pb are provided to line up with the probing electrode region Rt3 in the Y direction.

The other configurations are similar to those in the above embodiment, and similar effects to those in the above embodiment are obtained.

### Second Embodiment

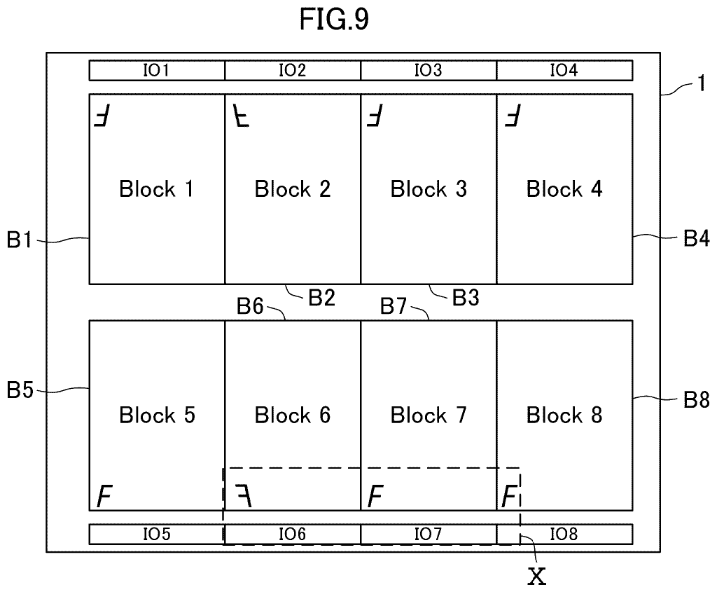

FIG. 9 is a plan view schematically showing the entire configuration of a semiconductor integrated circuit device of the second embodiment. In the second embodiment, also, it is decided that the horizontal direction in the figure is the X direction (corresponding to the second direction) and the vertical direction in the figure is the Y direction (corresponding to the first direction).

The semiconductor integrated circuit device 1 shown in FIG. 9 has eight functional blocks having the same function. In the following description, the eight functional blocks may be described distinctively under the respective reference codes B1 to B8. A semiconductor integrated circuit device 1 includes IO cell blocks IO1 to IO8 provided for the respective functional blocks B1 to B8.

The IO cell blocks IO1 to IO8 each have a plurality of IO cells. The IO cells include: a signal IO cell having an input/output circuit for exchanging signals with outside the chip and an ESD circuit; and a power IO cell having an ESD circuit. In the first embodiment described above, the IO cells 3 and 4 are examples of power IO cells, and the IO cells 5 are examples of signal IO cells.

To the IO cells, connected are electrode pads P formed in the uppermost metal interconnect layer MT (corresponding to the first interconnect layer, hereinafter called the “MT interconnect layer”) for probing and for connection with a package substrate or an interposer. The electrode pads P are placed on the functional blocks corresponding to the respective IO cell blocks IO1 to IO8.

In FIG. 9, the functional blocks B1 to B8, having the same layout structure except for electrode pads P and interconnects connected to the electrode pads, are placed in a horizontally inverted state and/or a vertically inverted state. The letters “F” in FIG. 9 indicate the inverted states of the functional blocks B1 to B8. Note that, although the semiconductor integrated circuit device 1 also has blocks other than those shown in FIG. 9, illustration of such blocks is omitted here.

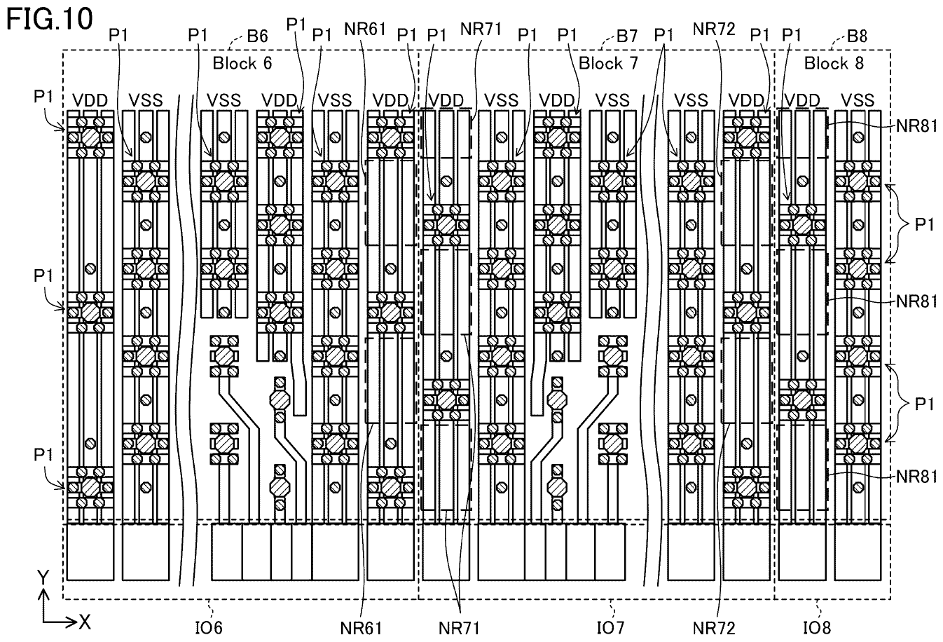

FIG. 10 shows an example of the layout of the MT interconnect layer in range X in FIG. 9, illustrating, as an enlarged view, the boundary portion between the functional block B6 and the functional block B7 and the boundary portion between the functional block B7 and the functional block B8. Note that, in FIG. 10, the configuration of four columns from the right end of the functional block B6 in the figure correspond to the four columns from the right end in FIG. 1 described above. Also, the configuration of two columns from the left end of the functional block B6 in the figure correspond to the two columns from the left end in FIG. 1 described above.

That is, in FIG. 10, power lines Xv similar to those in FIGS. 2 to 6 are laid in the Mx interconnect layer (corresponding to the second interconnect layer). Also, although not illustrated, the inverted (e.g., horizontally inverted and vertically inverted) states of the functional blocks B1 to B8 also affect the placement of interconnects and elements in the Mx interconnect layer and further lower interconnect layers.

As described above, in this embodiment, all the functional blocks B1 to B8 have similar layouts including the layouts of the MT interconnect layer and the Mx interconnect layer (including the electrode pads P). Therefore, since the parasitic capacitance with interconnects in an interconnect layer below the Mx interconnect layer is uniform, and therefore the delay of signals between the functional blocks is uniform, no modification is necessary due to difference in timing among the functional blocks.

In this embodiment, all the functional blocks B1 to B8 have similar layout configurations as described above. However, placement of electrode pads P along the block boundaries may be different among the functional blocks B1 to B8.

Specifically, in placement of a plurality of electrode pads P along a boundary between adjacent functional blocks in the X direction, electrode pads P in one of the adjacent functional blocks are placed at positions displaced in the Y direction from electrode pads P placed at the boundary in the other functional block.

More specifically, in the example of FIG. 10, in the functional block B6, the first electrode pads P1 for VDD are arranged in the Y direction along the boundary with the functional block B7. Also, in the functional block B7, which is horizontally inverted from the functional block B6, the first electrode pads P1 for VDD are arranged in the Y direction along the boundary with the functional block B6.

In the above case, in the functional block B6, first electrode pads P1 in dashed-line frames NR61, among the first electrode pads P1 placed along the boundary with the functional block B7, are deleted. Similarly, in the functional block B7, first electrode pads P1 in dashed-line frames NR71, among the first electrode pads P1 placed along the boundary with the functional block B6, are deleted. In this way, by deleting the electrode pads P arranged along the boundary between the adjacent functional blocks alternately in the Y direction, achieved is a staggered state in which the positions of the first electrode pads P1 placed along the boundary between the adjacent functional blocks B6 and B7 are alternately displaced.

Also, in the example of FIG. 10, in the functional block B7, the first electrode pads P1 for VDD are arranged in the Y direction along the boundary with the functional block B8. Also, in the functional block B8, which is not horizontally inverted from the functional block B7, the first electrode pads P1 for VDD are arranged in the Y direction along the boundary with the functional block B7.

In the above case, in the functional block B7, first electrode pads P1 in dashed-line frames NR72, among the first electrode pads P1 placed along the boundary with the functional block B8, are deleted. Similarly, in the functional block B8, first electrode pads P1 in dashed-line frames NR81, among the first electrode pads P1 placed along the boundary with the functional block B7, are deleted. In this way, by deleting the electrode pads P arranged along the boundary between the adjacent functional blocks alternately in the Y direction, achieved is a staggered state in which the positions of the first electrode pads P1 placed along the boundary between the adjacent functional blocks B7 and B8 are alternately displaced.

As described above, by alternately displacing the positions of the first electrode pads P1 in the Y direction between the adjacent functional blocks, the problem that the proximity of the electrode pads P to each other makes the assembly difficult is avoided. Note that the reason why the electrode pads P arranged along the boundary between the adjacent functional blocks are deleted alternately in the Y direction is to avoid the current supply capability from largely decreasing due to one-sided decrease in the number of electrode pads P for power supply in one functional block.

According to the present disclosure, in a semiconductor integrated circuit device, it is possible to prevent or reduce occurrence of a power supply voltage drop without causing the problem of reliability. Therefore, the present disclosure is especially useful when electrode pads are placed on the entire chip in LSI, for example.

1. A semiconductor integrated circuit device, comprising:
a plurality of electrode pads arranged in a first direction in a first interconnect layer and connected to a common power supply;
a first interconnect extending in the first direction in the first interconnect layer and connecting the plurality of electrode pads mutually; and
a second interconnect extending in the first direction in a second interconnect layer located one layer below the first interconnect layer, having a first overlap portion overlapping the first interconnect in planar view, and connected to the first interconnect, wherein
each of the plurality of electrode pads includes a probing electrode pad and a bump- forming electrode pad, and
the second interconnect has a second overlap portion overlapping the probing electrode pad of each of the electrode pads in planar view.

2. The semiconductor integrated circuit device of claim 1, wherein
the second interconnect has a third overlap portion overlapping the bump-forming electrode pad in planar view.

3. The semiconductor integrated circuit device of claim 1, wherein
the probing electrode pad and the bump-forming electrode pad are formed separately from each other, and
the bump-forming electrode pad is constituted by a plurality of bump-forming electrode pads, and the plurality of bump-forming electrode pads are placed to surround the probing electrode pad.

4. The semiconductor integrated circuit device of claim 1, wherein
the probing electrode pad and the bump-forming electrode pad are formed integrally, and
the bump-forming electrode pad is placed to surround the probing electrode pad.

5. The semiconductor integrated circuit device of claim 1, wherein
the second interconnect is constituted by a plurality of third interconnects extending in parallel in the first direction, and
in place of part of the plurality of third interconnects, a signal interconnect extending in the first direction is formed separately from the third interconnects.

6. The semiconductor integrated circuit device of claim 1, comprising
a plurality of functional blocks each including the plurality of electrode pads, the first interconnect, and the second interconnect, having the same function, and arranged in a second direction perpendicular to the first direction, wherein
when the plurality of electrode pads are to be placed along a boundary between adjacent functional blocks in the second direction, the electrode pads at the boundary in one of the adjacent functional blocks are placed at positions displaced in the first direction from the electrode pads placed at the boundary in the other functional block.

7. A semiconductor integrated circuit device, comprising:
a first electrode pad and a second electrode pad arranged in a first direction in a first interconnect layer;
a first interconnect extending in the first direction in the first interconnect layer and connected to the first electrode pad;
a second interconnect connected to the second electrode pad in the first interconnect layer and formed separately from the first interconnect, and
a third interconnect extending in the first direction in a second interconnect layer located one layer below the first interconnect layer, having a first overlap portion overlapping the first interconnect in planar view, and connected to the first interconnect, wherein
each of the first electrode pad and the second electrode pad includes an probing electrode pad and an bump-forming electrode pad, and
the third interconnect is laid to have a second overlap portion overlapping the probing electrode pad of the first electrode pad in planar view, but to avoid an overlap with the probing electrode pad of the second electrode pad in planar view.

8. The semiconductor integrated circuit device of claim 7, wherein
the third interconnect has a third overlap portion overlapping the bump-forming electrode pad in planar view.

9. The semiconductor integrated circuit device of claim 7, wherein
the bump-forming electrode pad has an outer region located outside an end of the probing electrode pad in a second direction perpendicular to the first direction, and
the third interconnect has a fourth overlap portion overlapping the outer region in planar view.

10. The semiconductor integrated circuit device of claim 8, wherein
the bump-forming electrode pad has an outer region located outside an end of the probing electrode pad in a second direction perpendicular to the first direction, and
the third interconnect has a fourth overlap portion overlapping the outer region in planar view.

11. The semiconductor integrated circuit device of claim 7, wherein
in the second electrode pad, the bump-forming electrode pad is arranged in line with the probing electrode pad in the first direction, and
the third interconnect has a third overlap portion overlapping the bump-forming electrode pad.

12. The semiconductor integrated circuit device of claim 7, wherein
the third interconnect is constituted by a plurality of fourth interconnects arranged in a direction perpendicular to the first direction, and
in place of part of the plurality of fourth interconnects, a signal interconnect extending in the first direction is formed separately from the fourth interconnects.

13. The semiconductor integrated circuit device of claim 7, comprising
a plurality of functional blocks each including the first electrode pad, the second electrode pad, the first interconnect, the second interconnect, and the third interconnect, having the same function, and arranged in a direction perpendicular to the first direction, wherein
when the first electrode pad and the second electrode pad are to be placed at a boundary between adjacent functional blocks in the second direction, the first electrode pad and the second electrode pad at the boundary in one of the adjacent functional blocks are placed at positions displaced in the first direction from the first electrode pad and the second electrode pad at the boundary in the other functional block.
